(19) United States
(12) Patent Application Publication
(10) Pub. No.: US 2026/0291434 A1
(43) Pub. Date: Sep. 24, 2026

(54) Oscillator

(71) Applicant: SEIKO EPSON CORPORATION, Tokyo (JP)

(72) Inventor: Yoshiaki MATSUMOTO, Ina (JP)

(21) Appl. No.: 19/570,844

(22) Filed: Mar. 18, 2026

(30) Foreign Application Priority Data
Mar. 19, 2025 (JP) 2025-045389

(51) Int. Cl. H03B 1/02; H03B 5/32

(52) U.S. Cl. CPC H03B 1/02; H03B 5/32; H03B 2200/0014

(57) ABSTRACT

An oscillator includes: a first package that houses a resonator element and a circuit element that outputs an oscillation signal, and has a first side extending in a first direction and a second side extending in a second direction orthogonal to the first direction, and in which a first power supply terminal present along the first side and a filter terminal are disposed; and a second package that houses the first package, a first capacitor disposed adjacent to the first package and along the first side, and a second capacitor disposed adjacent to the first package and along the second side. The first power supply terminal and a first end of the first capacitor are electrically coupled by first wiring disposed in an inner layer of the second package. The filter terminal and a first end of the second capacitor are electrically coupled by second wiring disposed in the inner layer of the second package.

The present application is based on, and claims priority from JP Application Serial Number 2025-045389, filed Mar. 19, 2025, the disclosure of which is hereby incorporated by reference herein in its entirety.

### BACKGROUND

### 1. Technical Field

The present disclosure relates to an oscillator.

### 2. Related Art

JP-A-2014-53663 discloses a piezoelectric oscillator in which a piezoelectric resonator having a built-in resonator element, an integrated circuit (IC) for driving the resonator element, and two chip capacitors coupled to the IC are housed in a package, a terminal electrode of the piezoelectric resonator and a terminal electrode of the IC are coupled by a wire, and the terminal electrode of the IC and a pad electrode of the package are coupled by a wire.

However, in the piezoelectric oscillator described in JP-A-2014-53663, since the terminal electrode of the IC and the pad electrode of the package are coupled by the wire, an electronic component cannot be disposed in a region where the wires are present inside the package, and it is difficult to dispose one of the two chip capacitors in a region close to the IC. Therefore, since wiring that couples the IC and the one of the chip capacitors is long, and noise is easily superimposed on the wiring, a noise reduction effect by the chip capacitor is reduced, and it is difficult to improve the characteristics of the piezoelectric oscillator.

### SUMMARY

According to an aspect of the present disclosure, there is provided an oscillator including a resonator element; a circuit element that drives the resonator element and outputs an oscillation signal; a first package housing the resonator element and the circuit element and having a first side extending in a first direction and a second side extending in a second direction orthogonal to the first direction; a first power supply terminal disposed in the first package and along the first side; a filter terminal disposed in the first package; a first capacitor disposed adjacent to the first package and along the first side; a second capacitor disposed adjacent to the first package and along the second side; and a second package housing the first package, the first capacitor, and the second capacitor, wherein the first power supply terminal and a first end of the first capacitor are electrically coupled by first wiring disposed in an inner layer of the second package, and the filter terminal and a first end of the second capacitor are electrically coupled by second wiring disposed in the inner layer of the second package.

### BRIEF DESCRIPTION OF THE DRAWINGS

FIG. 1 is a functional block diagram of an oscillator according to the present embodiment.

FIG. 2 is a perspective view of an internal oscillator.

FIG. 3 is a top view of the internal oscillator.

FIG. 4 is a cross-sectional view of the internal oscillator.

FIG. 5 is a bottom view of the internal oscillator.

FIG. 6 is a perspective view of the oscillator according to the present embodiment.

FIG. 7 is a top view of the oscillator according to the present embodiment.

FIG. 8 is a cross-sectional view of the oscillator according to the present embodiment.

FIG. 9 is a diagram illustrating an example of electrodes and wiring disposed in a wiring layer.

FIG. 10 is a diagram illustrating an example of electrodes and wiring disposed in a wiring layer.

FIG. 11 is a diagram illustrating an example of electrodes disposed in a wiring layer.

### DESCRIPTION OF EMBODIMENTS

Hereinafter, preferred embodiments of the present disclosure will be described in detail with reference to the drawings. It should be noted that the embodiments described below do not unduly limit the contents of the present disclosure described in the appended claims. In addition, all configurations described below are not necessarily essential components of the present disclosure.

### 1. Functional Configuration of Oscillator

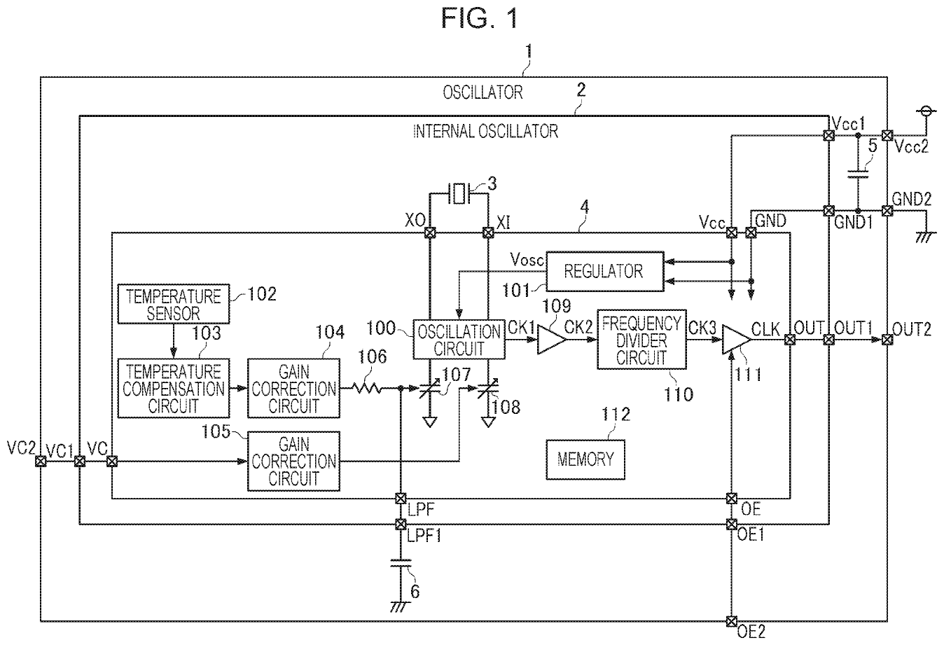

FIG. 1 is a functional block diagram illustrating an example of a functional configuration of an oscillator according to the present embodiment. As illustrated in FIG. 1, an oscillator 1 according to the present embodiment includes an internal oscillator 2 and two capacitors 5 and 6 and includes a terminal Vcc2, a terminal GND2, a terminal OUT2, a terminal VC2, and a terminal OE2 as external coupling terminals. The internal oscillator 2 includes a terminal Vcc1, a terminal GND1, a terminal OUT1, a terminal VC1, a terminal OE1, and a terminal LPF1 as external coupling terminals.

The terminal Vcc2 is a power supply terminal through which a power supply voltage is supplied from the outside of the oscillator 1, and is electrically coupled to the terminal Vcc1 that is also a power supply terminal. The terminal GND2 is a ground terminal through which a ground voltage is supplied from the outside of the oscillator 1, and is electrically coupled to the terminal GND1 that is also a ground terminal. A first end of the capacitor 5 is electrically coupled to the terminal Vcc1 and the terminal Vcc2, and a second end of the capacitor 5 is electrically coupled to the terminal GND1 and the terminal GND2. The capacitor 5 functions as a bypass capacitor that stabilizes the power supply voltage by bypassing noise superimposed on the power supply voltage to the ground.

The terminal OUT1 is an output terminal that outputs an oscillation signal CLK generated by the oscillator 1, and the terminal OUT2 that is also an output terminal is electrically coupled to the terminal OUT1. The terminal VC2 is a frequency control terminal to which a signal for controlling a frequency of the oscillation signal CLK is input, and is electrically coupled to the terminal VC1 that is also a frequency control terminal. The terminal OE2 is an output control terminal to which a signal for controlling the output of the oscillation signal CLK is input, and is electrically coupled to the terminal OE1 that is also an output control terminal.

The terminal LPF1 is a filter terminal for constituting a low pass filter, and is electrically coupled to a first end of the capacitor 6. A second end of the capacitor 6 is electrically coupled to the terminal GND1 and the terminal GND2, and the ground voltage is supplied to the second end of the capacitor 6.

The internal oscillator 2 includes a resonator element 3 and a circuit element 4. The circuit element 4 drives the resonator element 3 and outputs the oscillation signal CLK. The resonator element 3 is a quartz crystal resonator element having quartz crystal as a substrate material. For example, the resonator element 3 is an AT cut quartz crystal resonator element or the like. As the substrate material of the resonator element 3, in addition to quartz crystal, a piezoelectric single crystal such as lithium tantalate or lithium niobate, a piezoelectric material such as piezoelectric ceramics such as lead zirconate titanate, or the like can be used. As an excitation unit of the resonator element 3, a unit that uses a piezoelectric effect may be used.

As illustrated in FIG. 1, the circuit element 4 includes a terminal Vcc, a terminal GND, a terminal OUT, a terminal VC, a terminal OE, a terminal LPF, a terminal XO, and a terminal XI as external coupling terminals. The terminal Vcc is a power supply terminal through which the power supply voltage is supplied, and is electrically coupled to the terminal Vcc1. The terminal GND is a ground terminal through which the ground voltage is supplied, and is electrically coupled to the terminal GND1. The terminal OUT is an output terminal that outputs the oscillation signal CLK, and is electrically coupled to the terminal OUT1. The terminal VC is a frequency control terminal to which the signal for controlling the frequency of the oscillation signal CLK is input, and is electrically coupled to the terminal VC1. The terminal OE is an output control terminal to which the signal for controlling the output of the oscillation signal CLK is input, and is electrically coupled to the terminal OE1. The terminal LPF is a filter terminal for constituting the low pass filter, and is electrically coupled to the terminal LPF1. The terminal XO is coupled to an electrode 3a (described later) of the resonator element 3, and the terminal XI is coupled to an electrode 3b (described later) of the resonator element 3.

As illustrated in FIG. 1, the circuit element 4 includes an oscillation circuit 100, a regulator 101, a temperature sensor 102, a temperature compensation circuit 103, gain correction circuits 104 and 105, a resistor 106, variable capacitance elements 107 and 108, a buffer circuit 109, a frequency divider circuit 110, a buffer circuit 111, and a memory 112. In the present embodiment, the circuit element 4 is implemented by a one-chip integrated circuit. However, at least a section of the circuit element 4 may be constituted by a discrete component.

The memory 112 stores various types of data for controlling an operation of each section of the circuit element 4.

The regulator 101 is electrically coupled to the terminal Vcc and the terminal GND. The power supply voltage is supplied to the regulator 101 from the outside of the oscillator 1 through the terminal Vcc2, the terminal Vcc1, and the terminal Vcc. The ground voltage is supplied to the regulator 101 from the outside of the oscillator 1 through the terminal GND2, the terminal GND1, and the terminal GND. The regulator 101 generates a constant voltage Vosc based on the power supply voltage and the ground voltage. For example, the regulator 101 generates the constant voltage Vosc based on an output voltage of a bandgap reference circuit. The voltage Vosc is supplied to the oscillation circuit 100.

The oscillation circuit 100 is electrically coupled to the terminal XO and the terminal XI, and generates an oscillation signal CK1 by causing the resonator element 3 to oscillate using the voltage Vosc supplied from the regulator 101 as a power supply voltage. The oscillation circuit 100 amplifies a signal from the terminal XO and outputs the amplified signal to the terminal XI. That is, the signal output from the resonator element 3 is input to the oscillation circuit 100 through the terminal XO, and the oscillation circuit 100 amplifies the signal and outputs the amplified signal to the resonator element 3 through the terminal XI, whereby the resonator element 3 oscillates.

The oscillation circuit 100 is electrically coupled to a first end of the variable capacitance element 107 and a first end of the variable capacitance element 108. A second end of the variable capacitance element 107 and a second end of the variable capacitance element 108 are electrically coupled to the terminal GND. The ground voltage is supplied to the second end of the variable capacitance element 107 and the second end of the variable capacitance element 108. The variable capacitance elements 107 and 108 function as load capacitance of the oscillation circuit 100, and a frequency of the oscillation signal CK1 changes in accordance with capacitance values of the variable capacitance elements 107 and 108. The variable capacitance elements 107 and 108 may be, for example, varactors (variable capacitance diodes) or may be a capacitance array in which a plurality of capacitance elements are coupled in parallel via a switch element.

The temperature sensor 102 detects the temperature of the circuit element 4 and outputs a temperature signal having a voltage corresponding to the temperature. The temperature sensor 102 is implemented by, for example, a circuit using temperature characteristics of the bandgap reference circuit and temperature characteristics of a diode element.

The temperature compensation circuit 103 generates a temperature compensation voltage for correcting the frequency-temperature characteristics of the oscillation signal CK1 output from the oscillation circuit 100, based on the temperature signal output from the temperature sensor 102 and temperature compensation data corresponding to the frequency-temperature characteristics of the resonator element 3. The temperature compensation data is stored in the memory 112.

The gain correction circuit 104 corrects the scale of the temperature compensation voltage output from the temperature compensation circuit 103. The gain of the gain correction circuit 104 is stored in the memory 112. The gain correction circuit 104 is coupled to a first end of the resistor 106, and a second end of the resistor 106 is electrically coupled to the variable capacitance element 107 and is further electrically coupled to the capacitor 6 via the terminal LPF and the terminal LPF1. Therefore, the temperature compensation voltage corrected by the gain correction circuit 104 is supplied to the variable capacitance element 107 through the low-pass filter constituted by the resistor 106 and the capacitor 6. Then, the capacitance value of the variable capacitance element 107 changes in accordance with the temperature compensation voltage, and thus a fluctuation in the oscillation frequency of the oscillation circuit 100 caused by a fluctuation in the temperature is canceled, and the frequency of the oscillation signal CK1 becomes substantially constant regardless of the temperature.

The gain correction circuit 105 is coupled to the terminal VC, and the frequency control signal for controlling the frequency of the oscillation signal CLK is input to the gain correction circuit 105 from the outside of the oscillator 1 through the terminal VC2, the terminal VC1, and the terminal VC. Thereafter, the gain correction circuit 105 outputs a frequency control voltage obtained by correcting the scale of the voltage of the frequency control signal. The gain of the gain correction circuit 105 is stored in the memory 112. The gain correction circuit 105 is electrically coupled to the variable capacitance element 108, and the frequency control voltage output from the gain correction circuit 105 is supplied to the variable capacitance element 108. Then, the capacitance value of the variable capacitance element 108 changes in accordance with the frequency control voltage, and thus the oscillation frequency of the oscillation circuit 100 changes, and the oscillation signal CK1 has a frequency corresponding to the voltage of the frequency control signal.

The buffer circuit 109 buffers the oscillation signal CK1 output from the oscillation circuit 100 and outputs a rectangular-wave oscillation signal CK2.

The frequency divider circuit 110 outputs an oscillation signal CK3 obtained by dividing a frequency of the oscillation signal CK2 output from the buffer circuit 109. The frequency division ratio of the frequency divider circuit 110 is stored in the memory 112.

The buffer circuit 111 is electrically coupled to the terminal OE, and an output control signal for controlling the output of the oscillation signal CLK is input to the buffer circuit 111 from the outside of the oscillator 1 through the terminal OE2, the terminal OE1, and the terminal OE. When the output control signal becomes a high level, the buffer circuit 111 buffers the oscillation signal CK3 output from the frequency divider circuit 110 and outputs the oscillation signal CLK. When the output control signal becomes a low level, the output impedance of the buffer circuit 111 becomes high, and the buffer circuit 111 outputs, for example, an oscillation signal CLK having the ground voltage. The buffer circuit 111 is electrically coupled to the terminal OUT, and outputs the oscillation signal CLK to the outside of the oscillator 1 through the terminal OUT, the terminal OUT1, and the terminal OUT2.

Each of the oscillator 1 and the internal oscillator 2 configured as described above is a voltage-controlled temperature-compensated oscillator such as a VC-TCXO having a temperature compensation function and a frequency control function. VC-TCXO is an abbreviation for Voltage-Controlled Temperature-Compensated Crystal Oscillator.

### 2. Structure of Internal Oscillator

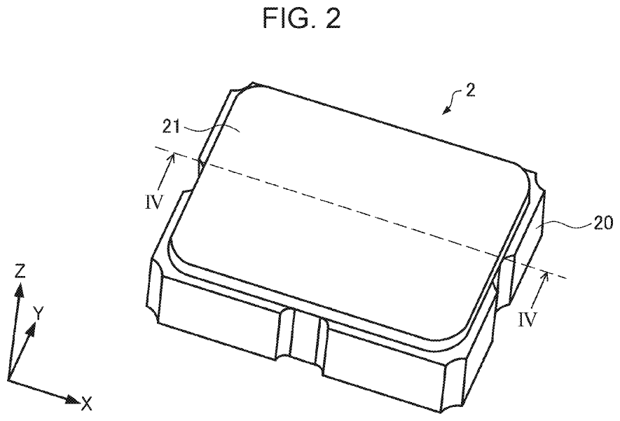

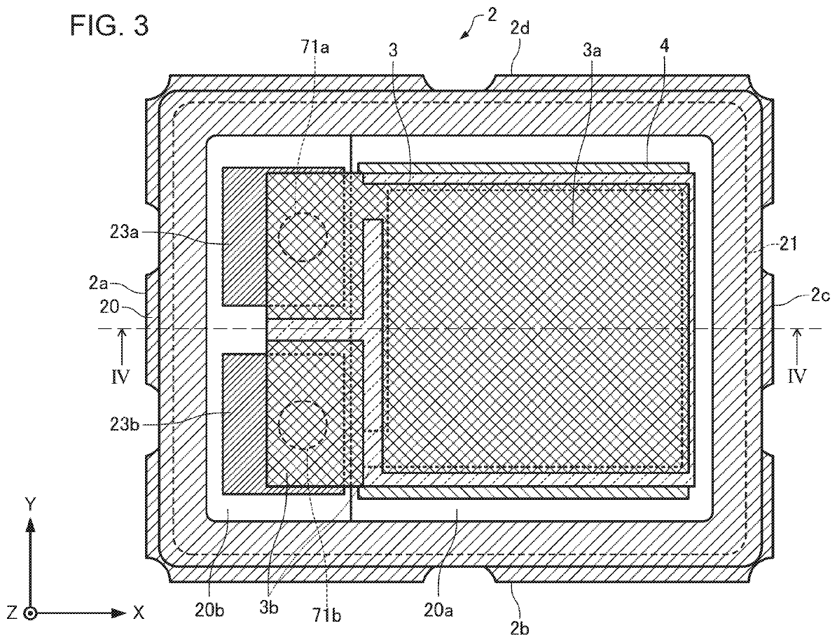

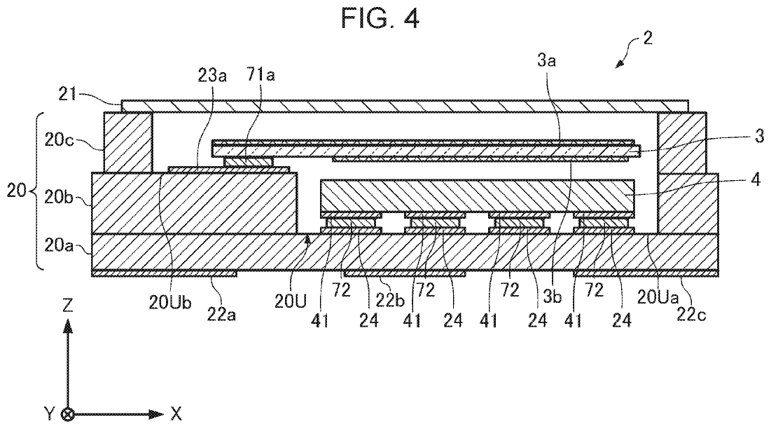

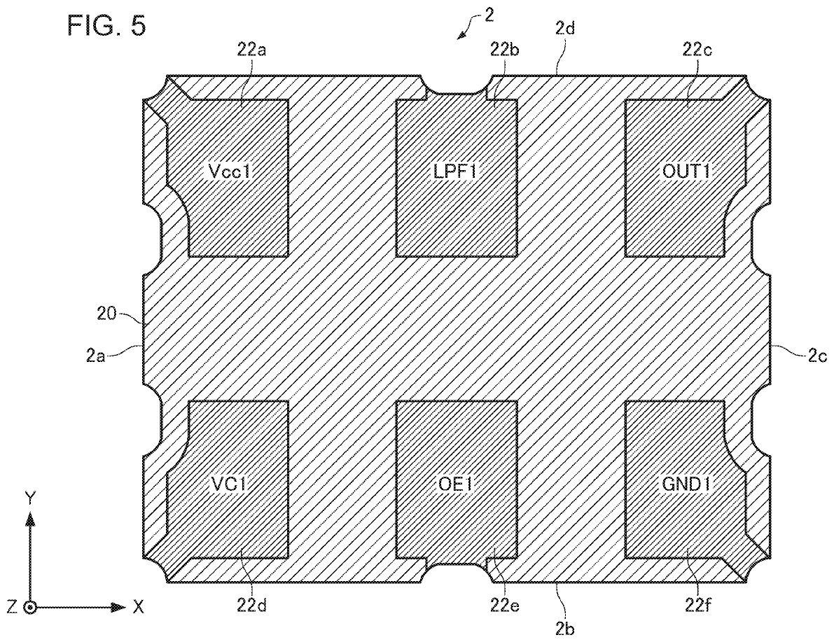

FIGS. 2 to 5 are diagrams illustrating an example of a structure of the internal oscillator 2. FIG. 2 is a perspective view of the internal oscillator 2. FIG. 3 is a top view of the internal oscillator 2. FIG. 4 is a cross-sectional view taken along line IV-IV illustrated in FIGS. 2 and 3. FIG. 5 is a bottom view of the internal oscillator 2. FIG. 5 is a perspective view when a bottom surface of the internal oscillator 2 is viewed from a top surface of the internal oscillator 2. FIGS. 2 to 5 illustrate an X direction, a Y direction, and a Z direction that are orthogonal to each other to understand the relationship between the directions.

As illustrated in FIGS. 2 to 5, the internal oscillator 2 includes the resonator element 3, the circuit element 4, a package 20, and a lid 21. FIG. 3 is the top view of the internal oscillator 2 with the lid 21 removed.

As illustrated in FIG. 3, the package 20 has a side 2a extending in the Y direction, a side 2b extending in the X direction, a side 2c extending in the Y direction and opposite to the side 2a, and a side 2d extending in the X direction and opposite to the side 2b in plan view as viewed in the Z direction. That is, the package 20 has a substantially rectangular shape in plan view as viewed in the Z direction.

In FIGS. 2 to 5, the resonator element 3 is an AT cut quartz crystal resonator element, but may be an SC cut quartz crystal resonator element, a BT cut quartz crystal resonator element, a tuning fork type quartz crystal resonator element, a surface acoustic wave resonator, another piezoelectric resonator element, an electrostatic drive type micro-electromechanical systems (MEMS) resonator element, or the like. MEMS is an abbreviation for Micro-ElectroMechanical Systems. Further, in FIGS. 2 to 5, the circuit element 4 is a one-chip integrated circuit, but at least a portion of the circuit element 4 may be constituted by a discrete component.

The internal oscillator 2 has a single seal structure, and the package 20 is a container that houses the resonator element 3 and the circuit element 4 in the same space. The package 20 includes a substrate 20a, a frame-shaped sidewall 20b joined to the substrate 20a, and a frame-shaped sidewall 20c joined to the frame-shaped sidewall 20b. The substrate 20a and the frame-shaped sidewalls 20b and 20c form a recessed portion 20U. The resonator element 3 and the circuit element 4 are housed in an airtight internal space formed by covering the recessed portion 20U with the lid 21. This makes it possible to protect the resonator element 3 and the circuit element 4 from an impact and an external environment, particularly, dust, moisture, humidity, and the like. Although not particularly limited, the package 20 can be made of ceramics such as alumina, and the lid 21 can be made of a metal material such as Kovar.

The atmosphere of the internal space is not particularly limited. For example, it is preferable that the atmosphere be replaced with an inert gas such as nitrogen or argon and that the internal space be in a reduced pressure state in which the pressure is reduced with respect to the atmospheric pressure, or be in a state closer to vacuum. Thus, the viscous resistance is reduced, the Q value of the resonator element 3 can be effectively lowered, and the oscillation characteristics of the resonator element 3 are improved. However, the atmosphere of the internal space is not limited thereto, and the internal space may be in an atmospheric pressure state or a pressurized state.

The recessed portion 20U has a step, and includes a recessed portion 20Ua formed by the substrate 20a and the frame-shaped sidewall 20b, and a recessed portion 20Ub formed by the frame-shaped sidewalls 20b and 20c and having an opening smaller than that of the recessed portion 20Ua. Two electrodes 23a and 23b arranged along the side 2a and in the Y direction are disposed on a bottom surface of the recessed portion 20Ub, that is, on a top surface of the frame-shaped sidewall 20b. Then, the electrode 23a is electrically coupled to the electrode 3a disposed on an upper surface of the resonator element 3 via a joining member 71a, and the electrode 23b is electrically coupled to the electrode 3b disposed on a lower surface of the resonator element 3 via a joining member 71b. In addition, the resonator element 3 is fixed to the bottom surface of the recessed portion 20Ub, that is, to an upper surface of the substrate 20a by the joining members 71a and 71b. That is, the resonator element 3 is attached to the package 20 at the positions of the joining members 71a and 71b.

A plurality of electrodes 24 are disposed on a bottom surface of the recessed portion 20Ua, that is, on an upper surface of the substrate 20a. Each of the plurality of electrodes 24 is electrically coupled to a corresponding one of a plurality of electrodes 41 disposed on a lower surface of the circuit element 4 via a corresponding one of a plurality of joining members 72. The circuit element 4 is fixed to the bottom surface of the recessed portion 20Ua, that is, to the upper surface of the substrate 20a by the plurality of joining members 72. That is, the circuit element 4 is flip-chip mounted on the upper surface of the substrate 20a. The plurality of electrodes 41 correspond to the terminal Vcc, the terminal GND, the terminal OUT, the terminal VC, the terminal OE, the terminal LPF, the terminal XO, and the terminal XI illustrated in FIG. 1.

The joining members 71a, 71b, and 72 are not particularly limited as long as the joining members 71a, 71b, and 72 have conductivity and a joining property. For example, as the joining members 71a, 71b, and 72, various metal bumps such as gold bumps, silver bumps, copper bumps, and solder bumps, and conductive adhesives in which conductive fillers such as silver fillers are dispersed in various adhesives such as polyimide-based, epoxy-based, silicone-based, and acrylic-based adhesives can be used.

As illustrated in FIG. 5, six electrodes 22a to 22f are disposed on the bottom surface of the internal oscillator 2, that is, on a bottom surface of the package 20. The electrode 22a corresponds to the terminal Vcc1, the electrode 22b corresponds to the terminal LPF1, the electrode 22c corresponds to the terminal OUT1, the electrode 22d corresponds to the terminal VC1, the electrode 22e corresponds to the terminal OE1, and the electrode 22f corresponds to the terminal GND. In other words, the terminal Vcc1, the terminal LPF1, the terminal OUT1, the terminal VC1, the terminal OE1, and the terminal GND1 are disposed on the bottom surface of the package 20.

The electrodes 22a and 22d are disposed along the side 2a, and the electrodes 22c and 22f are disposed along the side 2c. The electrodes 22d, 22e, and 22f are disposed along the side 2b, and the electrodes 22a, 22b, and 22c are disposed along the side 2d. That is, the electrode 22a is disposed at a corner where the sides 2a and 2d intersect, the electrode 22c is disposed at a corner where the sides 2c and 2d intersect, the electrode 22d is disposed at a corner where the sides 2a and 2b intersect, and the electrode 22f is disposed at a corner where the sides 2b and 2c intersect.

The two electrodes 41 corresponding to the terminal XI and the terminal XO of the circuit element 4 and wiring (not illustrated) for electrically coupling the two electrodes 3a and 3b of the resonator element 3 are disposed inside the package 20 or on the surface of the recessed portion 20U. Wiring (not illustrated) for electrically coupling the six electrodes 41 corresponding to the terminal Vcc, the terminal LPF, the terminal OUT, the terminal VC, the terminal OE, and the terminal GND of the circuit element 4 to the six electrodes 22a, 22b, 22c, 22d, 22e, and 22f corresponding to the terminal Vcc1, the terminal LPF1, the terminal OUT1, the terminal VC1, the terminal OE1, and the terminal GND1 of the internal oscillator 2 is disposed inside the package 20 or on the surface of the recessed portion 20U.

### 3. Structure of Oscillator

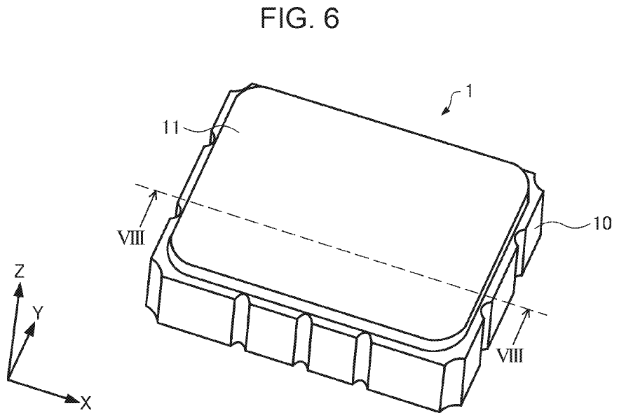

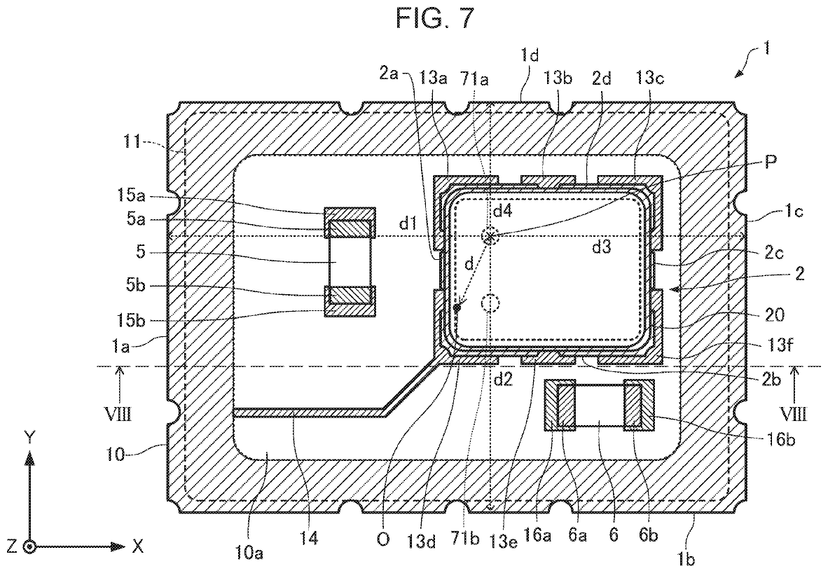

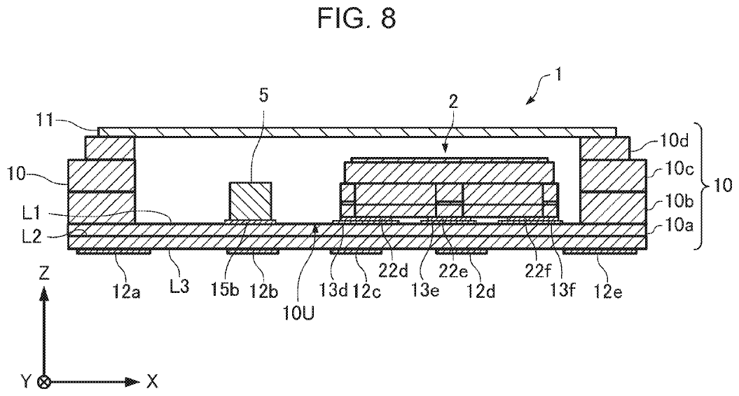

FIGS. 6 to 11 are diagrams illustrating an example of a structure of the oscillator 1. FIG. 6 is a perspective view of the oscillator 1. FIG. 7 is a top view of the oscillator 1. FIG. 8 is a cross-sectional view taken along line VIII-VIII illustrated in FIGS. 6 and 7. FIGS. 6 to 11 illustrate the X direction, the Y direction, and the Z direction that are orthogonal to each other to understand the relationship between the directions. In FIGS. 6 to 11, the X direction, the Y direction, and the Z direction indicate the same three directions as in FIGS. 2 to 5.

As illustrated in FIGS. 6 to 8, the oscillator 1 includes the internal oscillator 2, the capacitors 5 and 6, a package 10, and a lid 11. FIG. 7 is the top view of the oscillator 1 with the lid 11 removed.

As illustrated in FIG. 7, the package 10 has a side 1a extending in the Y direction, a side 1b extending in the X direction, a side 1c extending in the Y direction and opposite to the side 1a, and a side 1d extending in the X direction and opposite to the side 1b in plan view as viewed in the Z direction. That is, the package 10 has a substantially rectangular shape in plan view as viewed in the Z direction.

The oscillator 1 has a double seal structure, and the package 10 is a container that houses the internal oscillator 2 having the package 20 and the capacitors 5 and 6 in the same space. The package 10 includes a substrate 10a, a frame-shaped sidewall 10b joined to the substrate 10a, a frame-shaped sidewall 10c joined to the frame-shaped sidewall 10b, and a frame-shaped sidewall 10d joined to the frame-shaped sidewall 10c. The substrate 10a and the frame-shaped sidewalls 10b, 10c, and 10d form a recessed portion 10U. The internal oscillator 2 and the capacitors 5 and 6 are housed in an internal space formed by covering the recessed portion 10U with the lid 11. This makes it possible to protect the internal oscillator 2 and the capacitors 5 and 6 from an impact and an external environment, particularly, dust, moisture, humidity, and the like. Although not particularly limited, the package 10 can be made of ceramics such as alumina, and the lid 11 can be made of a metal material such as Kovar.

The substrate 10a includes a wiring layer L1, a wiring layer L2, and a wiring layer L3. The wiring layer L1 is disposed on an upper surface of the substrate 10a, that is, on a bottom surface of the recessed portion 10U. The wiring layer L2 is disposed on an inner layer surface of the substrate 10a. The wiring layer L3 is disposed on a lower surface of the substrate 10a, that is, on a bottom surface of the package 10. In the following description, the wiring layer L1, the wiring layer L2, and the wiring layer L3 are electrically coupled by through-hole wiring, a via, substrate side-surface wiring, and the like disposed in the substrate 10a.

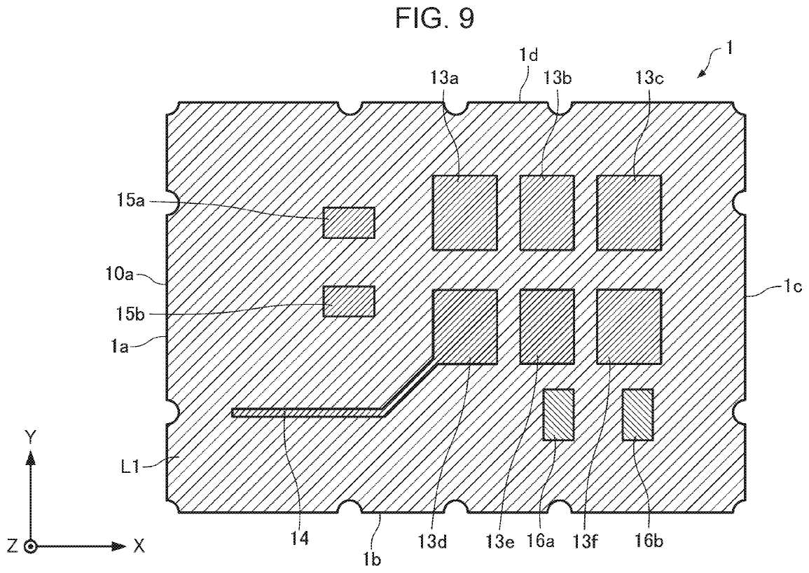

FIG. 9 is a diagram illustrating an example of electrodes and wiring disposed in the wiring layer L1. As illustrated in FIG. 9, electrodes 13a, 13b, 13c, 13d, 13e, 13f, 15a, 15b, 16a, and 16b, and wiring 14 extending from the electrode 13d are disposed in the wiring layer L1. As illustrated in FIGS. 7 and 8, the electrodes 13a, 13b, 13c, 13d, 13e, and 13f are electrically coupled to the electrodes 22a, 22b, 22c, 22d, 22e, and 22f disposed on the bottom surface of the internal oscillator 2 illustrated in FIG. 5 via a joining member (not illustrated) such as solder or a conductive adhesive, respectively. In other words, the electrode 13a is electrically coupled to the terminal Vcc1, the electrode 13b is electrically coupled to the terminal LPF1, the electrode 13c is electrically coupled to the terminal OUT1, the electrode 13d is electrically coupled to the terminal VC1, the electrode 13e is electrically coupled to the terminal OE1, and the electrode 13f is electrically coupled to the terminal GND1.

As illustrated in FIGS. 7 and 8, the electrodes 15a and 15b are electrically coupled to an electrode 5a, which is the first end of the capacitor 5, and an electrode 5b, which is the second end of the capacitor 5, via a joining member (not illustrated) such as solder or a conductive adhesive, respectively. In addition, the electrodes 16a and 16b are electrically coupled to an electrode 6a, which is the first end of the capacitor 6, and an electrode 6b, which is the second end of the capacitor 6, via a joining member (not illustrated) such as solder or a conductive adhesive, respectively.

As illustrated in FIG. 7, the capacitor 5 is adjacent to the side 2a of the package 20 of the internal oscillator 2. That is, the capacitor 5 is disposed in the vicinity of the side 2a, and no electronic component is present between the capacitor 5 and the side 2a. Further, the electrodes 5a and 5b that are the first end and the second end of the capacitor 5 are arranged in the Y direction. That is, since the first end and the second end of the capacitor 5 are arranged along the side 2a of the package 20, both a distance between the first end of the capacitor 5 and the terminal Vcc1 and a distance between the second end of the capacitor 5 and the terminal GND1 can be short.

Similarly, the capacitor 6 is adjacent to the side 2b of the package 20 of the internal oscillator 2. That is, the capacitor 6 is disposed in the vicinity of the side 2b, and no electronic component is present between the capacitor 6 and the side 2b. Further, the electrodes 6a and 6b that are the first end and the second end of the capacitor 6 are arranged in the X direction. That is, since the first end and the second end of the capacitor 6 are arranged along the side 2b of the package 20, both a distance between the first end of the capacitor 6 and the terminal LPF1 and a distance between the second end of the capacitor 6 and the terminal GND1 can be short.

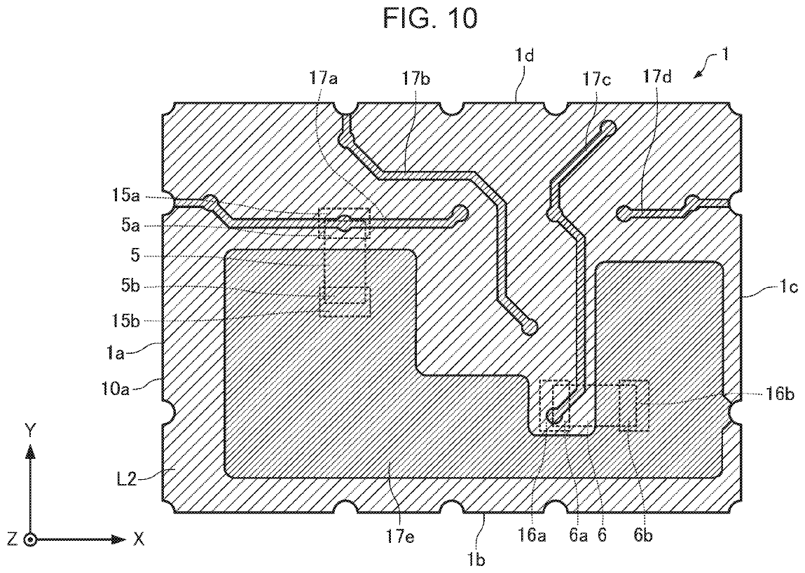

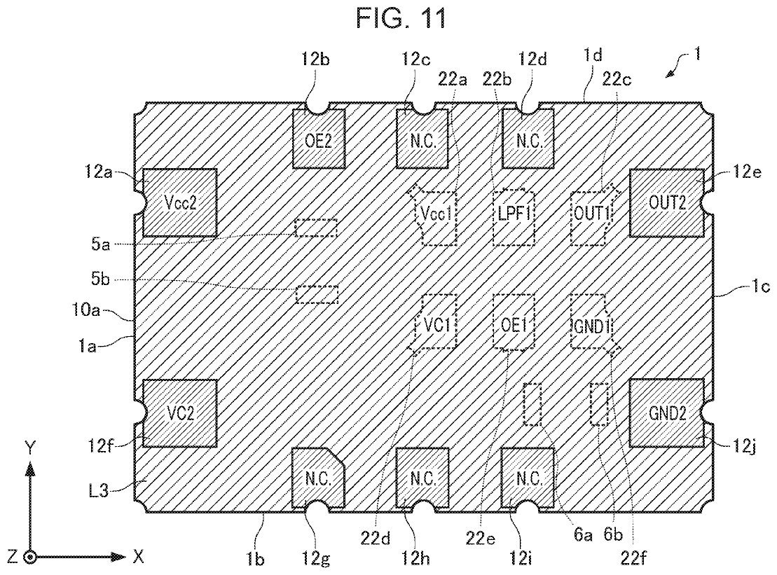

FIG. 10 is a diagram illustrating an example of electrodes and wiring disposed in the wiring layer L2. FIG. 11 is a diagram illustrating an example of electrodes disposed in the wiring layer L3. FIG. 11 is a perspective view when the lower surface of the substrate 10a is viewed from the upper surface of the substrate 10a. In FIG. 10, the capacitors 5 and 6 illustrated in FIG. 7 and the electrodes 15a, 15b, 16a, and 16b illustrated in FIG. 9 are indicated by broken lines. Further, in FIG. 11, the electrodes 5a, 5b, 6a, and 6b illustrated in FIG. 7 and the electrodes 22a to 22f of the internal oscillator 2 illustrated in FIG. 5 are indicated by broken lines.

As illustrated in FIG. 10, wiring 17a, 17b, 17c, 17d, and 17e is disposed in the wiring layer L2. The wiring 17e is a ground pattern.

As illustrated in FIG. 11, ten electrodes 12a to 12j are disposed in the wiring layer L3. The electrode 12a corresponds to the terminal Vcc2, the electrode 12b corresponds to the terminal OE2, the electrode 12e corresponds to the terminal OUT2, the electrode 12f corresponds to the terminal VC2, and the electrode 12j corresponds to the terminal GND2. In other words, the terminal Vcc2, the terminal OE2, the terminal OUT2, the terminal VC2, and the terminal GND2 are disposed on the bottom surface of the package 10. The electrodes 12c, 12d, 12g, 12h, and 12i are N.C. terminals. N.C. is an abbreviation for Non-Connection or No Connecting.

The electrodes 12a and 12f are disposed along the side 1a, and the electrodes 12e and 12j are disposed along the side 1c. The electrodes 12g, 12h, and 12i are disposed along the side 1b, and the electrodes 12b, 12c, and 12d are disposed along the side 1d.

As illustrated in FIGS. 9 to 11, the wiring 17a couples the electrode 12a, the electrode 15a, and the electrode 13a. That is, the wiring 17a couples the terminal Vcc2, the first end of the capacitor 5, and the terminal Vcc1. As described above, the terminal Vcc1 and the first end of the capacitor 5 are electrically coupled to each other and the first end of the capacitor 5 and the terminal Vcc2 are electrically coupled to each other by the wiring 17a disposed in the wiring layer L2 that is an inner layer of the package 10.

In addition, as illustrated in FIGS. 9 to 11, the wiring 17b couples the electrode 12b and the electrode 13e. That is, the wiring 17b couples the terminal OE2 and the terminal OE1. In this way, the terminal OE1 and the terminal OE2 are electrically coupled to each other by the wiring 17b disposed in the wiring layer L2 that is the inner layer of the package 10.

In addition, as illustrated in FIGS. 9 to 11, the wiring 17c couples the electrode 13b and the electrode 16a. That is, the wiring 17c couples the terminal LPF1 and the first end of the capacitor 6. In this way, the terminal LPF1 and the first end of the capacitor 6 are electrically coupled to each other by the wiring 17c disposed in the wiring layer L2 that is the inner layer of the package 10.

In addition, as illustrated in FIGS. 9 to 11, the wiring 17d couples the electrode 12e and the electrode 13c. That is, the wiring 17d couples the terminal OUT2 and the terminal OUT1. In this way, the terminal OUT1 and the terminal OUT2 are electrically coupled to each other by the wiring 17d disposed in the wiring layer L2 that is the inner layer of the package 10.

As illustrated in FIGS. 9 to 11, the wiring 17e couples the electrode 12j, the electrode 15b, the electrode 16b, and the electrode 13f. That is, the wiring 17e couples the terminal GND2, the second end of the capacitor 5, the second end of the capacitor 6, and the terminal GND1. As described above, the terminal GND1 is electrically coupled to each of the second ends of the capacitors 5 and 6 and each of the second ends of the capacitors 5 and 6 is electrically coupled to the terminal GND2 by the wiring 17e disposed in the wiring layer L2 that is the inner layer of the package 10.

In addition, as illustrated in FIGS. 9 to 11, the wiring 14 couples the electrode 12f and the electrode 13d. That is, the wiring 14 couples the terminal VC2 and the terminal VC1. In this way, the terminal VC1 and the terminal VC2 are electrically coupled by the wiring 14 disposed in the wiring layer L1 that is a surface layer of the package 10. If wiring coupling the terminal VC2 and the terminal VC1 is disposed in the wiring layer L2, the wiring is long in order to bypass the wiring 17e that is the ground pattern. However, as illustrated in FIG. 9, the wiring 14 can be short since the wiring 14 is disposed in the wiring layer L1.

As illustrated in FIG. 11, the electrode 12e is closest to the electrode 22c among the electrodes 22a to 22f disposed in the package 20. That is, the terminal OUT2 is closest to the terminal OUT1 among all the terminals disposed in the package 20, that is, among the terminal Vcc1, the terminal LPF1, the terminal OUT1, the terminal VC1, and the terminal OE1, and the terminal GND1. Therefore, since the wiring 17d coupling the terminal OUT2 and the terminal OUT1 is short, noise superimposed on the oscillation signal CLK output from the terminal OUT1 is reduced, and the phase-noise characteristics are improved.

Further, as illustrated in FIG. 11, the electrode 12f is closest to the electrode 22d among the electrodes 22a to 22f disposed in the package 20. That is, the terminal VC2 is closest to the terminal VC1 among all the terminals disposed in the package 20. Therefore, since the wiring 14 coupling the terminal VC2 and the terminal VC1 is short, noise superimposed on the frequency control signal input from the terminal VC2 is reduced, and the accuracy of the frequency of the oscillation signal CLK is improved.

Further, as illustrated in FIG. 11, the electrode 12a is closest to the electrode 22a among the electrodes 22a to 22f disposed in the package 20. That is, the terminal Vcc2 is closest to the terminal Vcc1 among all the terminals disposed in the package 20. Therefore, since the wiring 17a coupling the terminal Vcc2 and the terminal Vcc1 is short, noise superimposed on the power supply voltage supplied from the terminal Vcc2 is reduced. As a result, noise superimposed on the oscillation signal CLK via the terminal Vcc1 is reduced, and the phase-noise characteristics are improved.

Further, the electrode 5a that is the first end of the capacitor 5 is closest to the electrode 22a among the electrodes 22a to 22f disposed in the package 20. That is, the first end of the capacitor 5 is closest to the terminal Vcc1 among all the terminals disposed in the package 20. Therefore, the wiring 17a coupling the first end of the capacitor 5 and the terminal Vcc1 is short. In addition, as illustrated in FIG. 10, the electrode 6b that is the second end of the capacitor 5 overlaps the wiring 17e that is the ground pattern disposed in the wiring layer L2 that is the inner layer of the package 10 when the package 10 is viewed in plan view. That is, the second end of the capacitor 5 is directly coupled to the ground pattern having a large area. Therefore, the capacitor 5 can exhibit a high effect as a bypass capacitor that stabilizes the power supply voltage by bypassing the noise superimposed on the power supply voltage to the ground.

Further, as illustrated in FIG. 11, the electrode 12j is closest to the electrode 22f among the electrodes 22a to 22f disposed in the package 20. That is, the terminal GND2 is closest to the terminal GND1 among all the terminals disposed in the package 20. Therefore, since the wiring 17e coupling the terminal GND2 and the terminal GND1 is short, the noise superimposed on the ground voltage supplied from the terminal GND2 is reduced. As a result, noise superimposed on the oscillation signal CLK via the terminal GND1 is reduced, and the phase-noise characteristics are improved.

Further, the electrode 6b that is the second end of the capacitor 6 is closest to the electrode 22f among the electrodes 22a to 22f disposed in the package 20. That is, the second end of the capacitor 6 is closest to the terminal GND1 among all the terminals disposed in the package 20. Therefore, the wiring 17e coupling the second end of the capacitor 6 and the terminal GND1 is short. In addition, as illustrated in FIG. 10, the electrode 6b that is the second end of the capacitor 6 overlaps the wiring 17e that is the ground pattern disposed in the wiring layer L2 that is the inner layer of the package 10 when the package 10 is viewed in plan view. That is, the second end of the capacitor 6 is directly coupled to the ground pattern having the large area. Therefore, the low-pass filter constituted by the resistor 106 and the capacitor 6 illustrated in FIG. 1 can effectively reduce high-frequency noise superimposed on the temperature compensation voltage.

As described above, the resonator element 3 is attached to the package 20 at the positions of the joining members 71a and 71b. As illustrated in FIG. 7, in a case where the position of the joining member 71a is set as an attachment position P where the resonator element 3 is attached to the package 20, a distance d between the attachment position P and the center O of the package 10 is shorter than a distance d1 between the attachment position P and the side 1a and a distance d2 between the attachment position P and the side 1b. The distance d between the attachment position P and the center O of the package 10 is shorter than a distance d3 between the attachment position P and the side 1c and a distance d4 between the attachment position P and the side 1d. Even in a case where the position of the joining member 71b is set as the attachment position P, the distance d is shorter than the distances d1, d2, d3, and d4. That is, since the resonator element 3 is attached at a position near the center O of the package 10, coupling failure or deformation of the resonator element 3 is unlikely to occur even when stress is applied to the package 10. Therefore, even when stress is applied to the package 10, the accuracy of the frequency of the oscillation signal CLK is less likely to be reduced.

Further, in order to reduce the noise superimposed on the oscillation signal CLK output from the terminal OUT1 as much as possible, it is preferable to make the distance between the terminal OUT1 and the terminal OUT2 as short as possible as illustrated in FIG. 11. Then, as illustrated in FIG. 7, the internal oscillator 2 is disposed close to a corner where the side 1c and the side 1d of the package 10 intersect, and thus an L-shaped empty region is present on the substrate 10a of the package 10. Therefore, by arranging the capacitors 5 and 6 and the wiring 14 in the L-shaped region, it is possible to effectively utilize the empty region. Therefore, the oscillator 1 is made compact.

The Y direction is an example of a “first direction”, and the X direction is an example of a “second direction”. The package 20 is an example of a “first package”, the side 2a is an example of a “first side”, and the side 2b is an example of a “second side”. The package 10 is an example of a “second package”, the side 1a is an example of a “third side”, and the side 1b is an example of a “fourth side”. The terminal Vcc1 is an example of a “first power supply terminal”, and the terminal Vcc2 is an example of a “second power supply terminal”. The terminal GND1 is an example of a “first ground terminal”, and the terminal GND2 is an example of a “second ground terminal”. The terminal OUT1 is an example of a “first output terminal”, and the terminal OUT2 is an example of a “second output terminal”. The terminal VC1 is an example of a “first frequency control terminal”, and the terminal VC2 is an example of a “second frequency control terminal”. The capacitor 5 is an example of a “first capacitor”, and the capacitor 6 is an example of a “second capacitor”. The wiring 17a is an example of “first wiring”, and the wiring 17c is an example of “second wiring”.

### 4. Operational Effects

As described above, in the oscillator 1 according to the present embodiment, since the resonator element 3 and the circuit element 4 that drives the resonator element 3 are housed in the package 20, it is not necessary to couple the circuit element 4 and the package 10 to each other by a bonding wire. Therefore, on the upper surface of the substrate 10a that is a mounting surface of the package 10, a region for the bonding wire is not necessary and thus it is possible to dispose the capacitor 5 in the vicinity of the side 2a of the package 20 and to dispose the capacitor 6 in the vicinity of the side 2b of the package 20. Therefore, the wiring 17a that electrically couples the terminal Vcc1 disposed in the package 20 and the first end of the capacitor 5 is short, and the wiring 17c that electrically couples the terminal LPF1 disposed in the package 20 and the first end of the capacitor 6 is short. Further, since the terminal Vcc1 is disposed along the side 2a of the package 20, the wiring 17a is even shorter. Therefore, according to the oscillator 1 according to the present embodiment, noise superimposed on the wiring 17a and 17c is reduced, and the phase-noise characteristics of the oscillation signal CLK can be improved by the noise reduction effect of the capacitors 5 and 6.

In addition, in the oscillator 1 according to the present embodiment, since the resonator element 3 and the circuit element 4 that drives the resonator element 3 are housed in the package 20, and the package 20 is housed in the package 10, the resonator element 3 and the circuit element 4 are less likely to be affected by a change in the temperature of the outside air. Further, since the resonator element 3 and the circuit element 4 that drives the resonator element 3 are housed in the single package 20, the difference in temperature between the resonator element 3 and the circuit element 4 is small. Therefore, according to the oscillator 1 according to the present embodiment, the accuracy of the temperature compensation by the circuit element 4 is improved, and the frequency-temperature characteristics of the oscillation signal CLK are improved.

In addition, in the oscillator 1 according to the present embodiment, since the terminal OUT2 is closest to the terminal OUT1 among all the terminals disposed in the package 20, the wiring 17d coupling the terminal OUT1 and the terminal OUT2 is short. Therefore, according to the oscillator 1 according to the present embodiment, the noise superimposed on the oscillation signal CLK output from the terminal OUT1 is reduced, and the phase-noise characteristics of the oscillation signal CLK are improved.

In addition, in the oscillator 1 according to the present embodiment, since the terminal Vcc2 is closest to the terminal Vcc1 among all the terminals disposed in the package 20, the wiring 17a coupling the terminal Vcc2 and the terminal Vcc1 is short. Therefore, according to the oscillator 1 according to the present embodiment, since noise superimposed on the power supply voltage supplied from the terminal Vcc2 is reduced and noise superimposed on the oscillation signal CLK via the terminal Vcc1 is reduced, the phase-noise characteristics of the oscillation signal CLK are improved.

In addition, in the oscillator 1 according to the present embodiment, since the GND2 terminal is closest to the terminal GND1 among all the terminals disposed in the package 20, the wiring 17e coupling the terminal GND2 and the terminal GND1 is short. Therefore, according to the oscillator 1 according to the present embodiment, since the noise superimposed on the ground voltage supplied from the terminal GND2 is reduced and the noise superimposed on the oscillation signal CLK via the terminal GND1 is reduced, the phase-noise characteristics of the oscillation signal CLK are improved.

Further, in the oscillator 1 according to the present embodiment, since the terminal VC2 is closest to the terminal VC1 among all the terminals disposed in the package 20, the wiring 14 coupling the terminal VC2 and the terminal VC1 is short. Therefore, according to the oscillator 1 according to the present embodiment, the noise superimposed on the frequency control signal input from the terminal VC2 is reduced, and the accuracy of the frequency of the oscillation signal CLK is improved.

Further, according to the oscillator 1 according to the present embodiment, since the resonator element 3 is attached at the position near the center O of the package 10, even when stress is applied to the package 10, coupling failure or deformation of the resonator element 3 is unlikely to occur, and the accuracy of the frequency of the oscillation signal CLK is unlikely to be reduced.

In addition, in the oscillator 1 according to the present embodiment, since the first end of the capacitor 5 is closest to the terminal Vcc1 among all the terminals disposed in the package 20 and the second end of the capacitor 5 is directly attached to the ground pattern having the large area, the capacitor 5 can exhibit a high effect as a bypass capacitor that stabilizes the power supply voltage.

Further, in the oscillator 1 according to the present embodiment, since the second end of the capacitor 6 is closest to the terminal GND1 among all the terminals disposed in the package 20 and the second end of the capacitor 6 is directly attached to the ground pattern having the large area, the low-pass filter configured by the resistor 106 and the capacitor 6 can effectively reduce high-frequency noise superimposed on the temperature compensation voltage.

### 5. Modifications

The present disclosure is not limited to the present embodiment, and various modifications may be made without departing from the scope of the present disclosure.

For example, the oscillator 1 and the internal oscillator 2 according to the above-described embodiments are voltage-controlled temperature-compensated oscillators, but are not limited thereto. For example, each of the oscillator 1 and the internal oscillator 2 may be a temperature compensation oscillator such as a TCXO that does not have a frequency control function, or may be an oscillator such as an SPXO that does not have a temperature compensation function and a frequency control function. TCXO is an abbreviation of Temperature Compensated Crystal Oscillator, and SPXO is an abbreviation of Simple Packaged Crystal Oscillator.

The above-described embodiments and modifications are merely examples, and the present disclosure is not limited thereto. For example, each of the embodiments and the modifications may be combined as appropriate.

The present disclosure includes configurations that are substantially the same as the configurations described in the embodiments, for example, a configuration having the same function, method, and result as those in the embodiments, or a configuration having the same purposes and effects as those in the embodiments. Further, the present disclosure includes configurations in which non-essential sections of the configurations described in the embodiments are replaced. In addition, the present disclosure includes configurations that achieve the same effects as those in the embodiments or configurations that can achieve the same purposes as those of the configurations described in the embodiments. Furthermore, the present disclosure includes configurations in which a known technique is added to the configurations described in the embodiments.

The following contents are derived from the above-described embodiments and modifications.

In an aspect, an oscillator includes a resonator element; a circuit element that drives the resonator element and outputs an oscillation signal; a first package housing the resonator element and the circuit element and having a first side extending in a first direction and a second side extending in a second direction orthogonal to the first direction; a first power supply terminal disposed in the first package and along the first side; a filter terminal disposed in the first package; a first capacitor disposed adjacent to the first package and along the first side; a second capacitor disposed adjacent to the first package and along the second side; and a second package housing the first package, the first capacitor, and the second capacitor, wherein the first power supply terminal and a first end of the first capacitor are electrically coupled by first wiring disposed in an inner layer of the second package, and the filter terminal and a first end of the second capacitor are electrically coupled by second wiring disposed in the inner layer of the second package.

In the oscillator, since the resonator element and the circuit element that drives the resonator element are housed in the first package, it is not necessary to couple the circuit element and the second package to each other by a bonding wire. Therefore, since a region for the bonding wire is not necessary on a mounting surface of the second package, it is possible to dispose the first capacitor in the vicinity of the first side of the first package and to dispose the second capacitor in the vicinity of the second side of the first package. Therefore, the first wiring that electrically couples the first power supply terminal disposed in the first package and the first end of the first capacitor is short, and the second wiring that electrically couples the filter terminal disposed in the first package and the first end of the second capacitor is short. Further, since the first power supply terminal is disposed along the first side of the first package, the first wiring is even shorter. Therefore, according to the oscillator, it is possible to reduce noise superimposed on the first wiring and the second wiring and improve the phase noise characteristics of the oscillation signal by the noise reduction effect of the first capacitor and the second capacitor.

In the aspect, in the oscillator, a first output terminal that outputs the oscillation signal may be disposed in the first package, a second output terminal electrically coupled to the first output terminal may be disposed in the second package, and the second output terminal may be closest to the first output terminal among all terminals disposed in the first package.

According to the oscillator, since wiring coupling the first output terminal and the second output terminal is short, noise superimposed on the oscillation signal output from the first output terminal is reduced, and the phase noise characteristics are improved.

In the aspect, in the oscillator, a second power supply terminal electrically coupled to the first power supply terminal may be disposed in the second package, and the second power supply terminal may be closest to the first power supply terminal among all terminals disposed in the first package.

According to the oscillator, since wiring coupling the second power supply terminal and the first power supply terminal is short, noise superimposed on a power supply voltage supplied from the second power supply terminal is reduced. Therefore, noise superimposed on the oscillation signal via the first power supply terminal is reduced, and the phase noise characteristics are improved.

In the aspect, in the oscillator, a first ground terminal may be disposed in the first package, a second ground terminal electrically coupled to the first ground terminal may be disposed in the second package, and the second ground terminal may be closest to the first ground terminal among all terminals disposed in the first package.

According to the oscillator, since wiring coupling the second ground terminal and the first ground terminal is short, noise superimposed on a ground voltage supplied from the second ground terminal is reduced. Therefore, noise superimposed on the oscillation signal via the first ground terminal is reduced, and the phase noise characteristics are improved.

In the aspect, in the oscillator, a first frequency control terminal may be disposed in the first package, a second frequency control terminal to which a signal for controlling a frequency of the oscillation signal is input and that is electrically coupled to the first frequency control terminal may be disposed in the second package, and the second frequency control terminal may be closest to the first frequency control terminal among all terminals disposed in the first package.

According to the oscillator, since wiring coupling the second frequency control terminal and the first frequency control terminal is short, noise superimposed on a signal input from the second frequency control terminal is reduced. Therefore, the accuracy of the frequency of the oscillation signal is improved.

In the aspect, in the oscillator, the second package may have a third side extending in the first direction and a fourth side extending in the second direction, the resonator element may be attached to the first package, and a distance between an attachment position where the resonator element is attached to the first package and a center of the second package may be shorter than a distance between the attachment position and the third side and a distance between the attachment position and the fourth side.

In the oscillator, since the resonator element is attached at the position near the center of the second package, that is, at the position where the resonator element is not easily deformed even when stress is applied to the second package, coupling failure or deformation of the resonator element does not easily occur. Therefore, according to the oscillator, even when stress is applied to the second package, the accuracy of the frequency of the oscillation signal is less likely to be reduced.

In the aspect, in the oscillator, the first end of the first capacitor may be closest to the first power supply terminal among all terminals disposed in the first package.

According to the oscillator, since wiring coupling the first end of the first capacitor and the first power supply terminal is short, the first capacitor can exhibit a high effect as a bypass capacitor that stabilizes the power supply voltage.

In the aspect, in the oscillator, a first ground terminal may be disposed in the first package, and a second end of the second capacitor may be electrically coupled to the first ground terminal and may be closest to the first ground terminal among all terminals disposed in the first package.

According to the oscillator, since wiring coupling the second end of the second capacitor and the first ground terminal is short, a low-pass filter that includes the second capacitor can effectively reduce high-frequency noise.

In the aspect, in the oscillator, a first ground terminal may be disposed in the first package, and a second end of the first capacitor and a second end of the second capacitor may be electrically coupled to the first ground terminal, and may overlap a ground pattern disposed in an inner layer of the second package when the second package is viewed in plan view.

According to the oscillator, since the second end of the first capacitor and the second end of the second capacitor can be directly attached to the ground pattern having a large area, the first capacitor and the second capacitor can exhibit a high effect.

In the aspect, in the oscillator, the first end and the second end of the first capacitor may be arranged in the first direction, and the first end and the second end of the second capacitor may be disposed in the second direction.

According to the oscillator, since both ends of the first capacitor can be brought close to the first side of the first package, both a distance between the first end of the first capacitor and the first power supply terminal and a distance between the second end of the first capacitor and the first ground terminal can be short. Therefore, the first capacitor can exhibit a high effect as a bypass capacitor that stabilizes the power supply voltage. Further, according to the oscillator, since both ends of the second capacitor can be brought close to the second side of the first package, it is possible to make short both a distance between the first end of the second capacitor and the filter terminal and a distance between the second end of the second capacitor and the first ground terminal. Therefore, the low-pass filter that includes the second capacitor can effectively reduce high-frequency noise.

What is claimed is:

1. An oscillator comprising:
a resonator element;
a circuit element that drives the resonator element and outputs an oscillation signal;
a first package housing the resonator element and the circuit element and having a first side extending in a first direction and a second side extending in a second direction orthogonal to the first direction;
a first power supply terminal disposed in the first package and along the first side;
a filter terminal disposed in the first package;
a first capacitor disposed adjacent to the first package and along the first side;
a second capacitor disposed adjacent to the first package and along the second side; and
a second package housing the first package, the first capacitor, and the second capacitor, wherein
the first power supply terminal and a first end of the first capacitor are electrically coupled by first wiring disposed in an inner layer of the second package, and
the filter terminal and a first end of the second capacitor are electrically coupled by second wiring disposed in the inner layer of the second package.

2. The oscillator according to claim 1, wherein
a first output terminal that outputs the oscillation signal is disposed in the first package,
a second output terminal electrically coupled to the first output terminal is disposed in the second package, and
the second output terminal is closest to the first output terminal among all terminals disposed in the first package.

3. The oscillator according to claim 1, wherein
a second power supply terminal electrically coupled to the first power supply terminal is disposed in the second package, and
the second power supply terminal is closest to the first power supply terminal among all terminals disposed in the first package.

4. The oscillator according to claim 1, wherein
a first ground terminal is disposed in the first package,
a second ground terminal electrically coupled to the first ground terminal is disposed in the second package, and
the second ground terminal is closest to the first ground terminal among all terminals disposed in the first package.

5. The oscillator according to claim 1, wherein
a first frequency control terminal is disposed in the first package,
a second frequency control terminal to which a signal for controlling a frequency of the oscillation signal is input and that is electrically coupled to the first frequency control terminal is disposed in the second package, and
the second frequency control terminal is closest to the first frequency control terminal among all terminals disposed in the first package.

6. The oscillator according to claim 1, wherein
the second package has a third side extending in the first direction and a fourth side extending in the second direction,
the resonator element is attached to the first package, and
a distance between an attachment position where the resonator element is attached to the first package and a center of the second package is shorter than a distance between the attachment position and the third side and a distance between the attachment position and the fourth side.

7. The oscillator according to claim 1, wherein
the first end of the first capacitor is closest to the first power supply terminal among all terminals disposed in the first package.

8. The oscillator according to claim 1, wherein
a first ground terminal is disposed in the first package, and
a second end of the second capacitor is electrically coupled to the first ground terminal and is closest to the first ground terminal among all terminals disposed in the first package.

9. The oscillator according to claim 1, wherein
a first ground terminal is disposed in the first package, and
a second end of the first capacitor and a second end of the second capacitor are electrically coupled to the first ground terminal, and overlap a ground pattern disposed in an inner layer of the second package when the second package is viewed in plan view.

10. The oscillator according to claim 1, wherein
the first end and a second end of the first capacitor are arranged in the first direction, and
the first end and a second end of the second capacitor are arranged in the second direction.
